(19) United States
(12) Patent Application Publication
(10) Pub. No.: US 2026/0363127 A1
(43) Pub. Date: Nov. 12, 2026

(54) MANUFACTURING METHOD AND MANUFACTURING DEVICE FOR SEMICONDUCTOR ELEMENT

(71) Applicant: KYOCERA CORPORATION, Kyoto-shi, Kyoto (JP)

(72) Inventors: Kentaro MURAKAWA, Kyoto-shi (JP); Motohisa USAGAWA, Kyoto-shi (JP); Tomohiro KITABAYASHI, Kyoto-shi (JP); Kosuke OTA, Kyoto-shi (JP); Yoshinobu KAWAGUCHI, Kyoto-shi (JP); Takeshi KAMIKAWA, Kyoto-shi (JP)

(73) Assignee: KYOCERA CORPORATION, Kyoto-shi, Kyoto (JP)

(21) Appl. No.: 19/134,816

(22) PCT Filed: Dec. 4, 2023
(86) PCT No.: PCT/JP2023/043286

§ 371 Date: Jun. 2, 2025

(30) Foreign Application Priority Data
Dec. 5, 2022 (JP) 2022-194283

(51) Int. Cl. H10W 72/00; H10W 90/00

(52) U.S. Cl. CPC H10W 72/07332; H10W 72/07163; H10W 72/07173; H10W 72/07307; H10W 90/734

(57) ABSTRACT

This manufacturing method for a semiconductor element includes bonding a plurality of elements SL, each including a semiconductor layer 8 grown on a growth substrate TS, to a surface of a support substrate MS, applying an external force to a back surface UF of one of the growth substrate TS or the support substrate MS, thereby forming a pressure distribution having in-plane non-uniformity, and peeling the plurality of elements SL bonded to the support substrate MS from the growth substrate TS.

### TECHNICAL FIELD The present disclosure relates to a manufacturing method and a manufacturing device for a semiconductor element.

### BACKGROUND OF INVENTION

Patent Document 1 discloses a technique in which a plurality of semiconductor layers (GaN layers, for example) are formed on a growth substrate including a mask pattern by using an epitaxial lateral overgrowth (ELO) method, and each semiconductor layer is peeled from the growth substrate by using dicing tape.

### CITATION LIST

### Patent Literature

Patent Document 1: JP 2013-251304 A

### SUMMARY

A manufacturing method for a semiconductor element according to the present disclosure includes bonding a plurality of elements, each including a semiconductor layer grown on a growth substrate, to a surface of a support substrate, applying an external force to a back surface of one of the growth substrate or the support substrate, thereby forming a pressure distribution having in-plane non-uniformity, and peeling the plurality of elements bonded to the support substrate from the growth substrate.

### BRIEF DESCRIPTION OF THE DRAWINGS

FIG. 1 is a flowchart illustrating a manufacturing method for a semiconductor element according to the present embodiment.

FIG. 2 is a plan view illustrating a growth substrate and a plurality of elements.

FIG. 3 is a cross-sectional view illustrating the manufacturing method for a semiconductor element according to the present embodiment.

FIG. 4 is a cross-sectional view illustrating the manufacturing method for a semiconductor element according to the present embodiment.

FIG. 5 is a cross-sectional view illustrating the manufacturing method for a semiconductor element according to the present embodiment.

FIG. 6 is a plan view illustrating the manufacturing method for a semiconductor element according to the present embodiment.

FIG. 7 is a cross-sectional view illustrating the manufacturing method for a semiconductor element according to the present embodiment.

FIG. 8 is a cross-sectional view illustrating the manufacturing method for a semiconductor element according to the present embodiment.

FIG. 9 is a cross-sectional view illustrating the manufacturing method for a semiconductor element according to the present embodiment.

FIG. 10 is a cross-sectional view illustrating the manufacturing method for a semiconductor element according to the present embodiment.

FIG. 11 is a cross-sectional view illustrating the manufacturing method for a semiconductor element according to the present embodiment.

FIG. 12 is a cross-sectional view illustrating the manufacturing method for a semiconductor element according to the present embodiment.

FIG. 13 is a cross-sectional view illustrating the manufacturing method for a semiconductor element according to the present embodiment.

FIG. 14 is a cross-sectional view illustrating a manufacturing device for a semiconductor element according to the present embodiment.

FIG. 15 is a cross-sectional view illustrating the manufacturing device for a semiconductor element according to the present embodiment.

FIG. 16 is a flowchart illustrating the manufacturing method for a semiconductor element according to the present embodiment.

FIG. 17 is a cross-sectional view illustrating the manufacturing method for a semiconductor element according to the present embodiment.

FIG. 18 is a cross-sectional view illustrating the manufacturing method for a semiconductor element according to the present embodiment.

FIG. 19 is a cross-sectional view illustrating the manufacturing device for a semiconductor element according to the present embodiment.

FIG. 20 is a cross-sectional view illustrating the manufacturing device for a semiconductor element according to the present embodiment.

FIG. 21 is a plan view illustrating a configuration of a semiconductor substrate according to the embodiment.

FIG. 22 is a plan view illustrating a configuration of the semiconductor substrate according to the embodiment.

FIG. 23 is a cross-sectional view of FIGS. 21 and 22.

FIG. 24 is a cross-sectional view illustrating a configuration of the semiconductor substrate according to the embodiment.

FIG. 25 is a cross-sectional view illustrating a configuration of the semiconductor substrate according to the embodiment.

### DESCRIPTION OF EMBODIMENTS

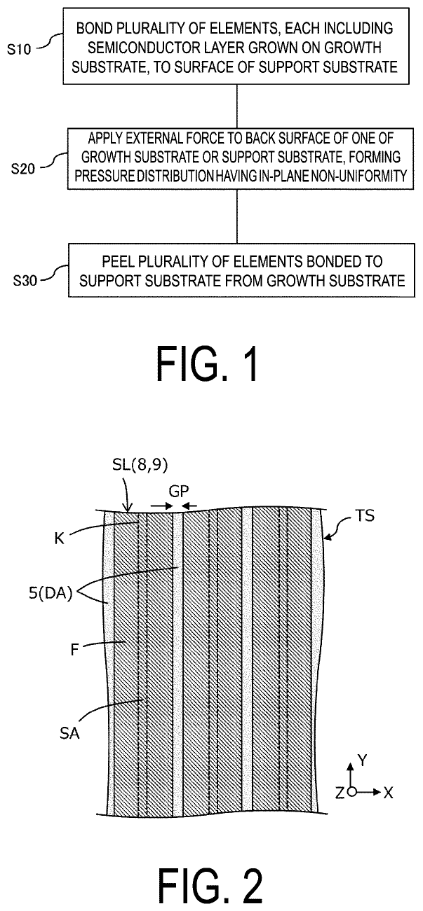

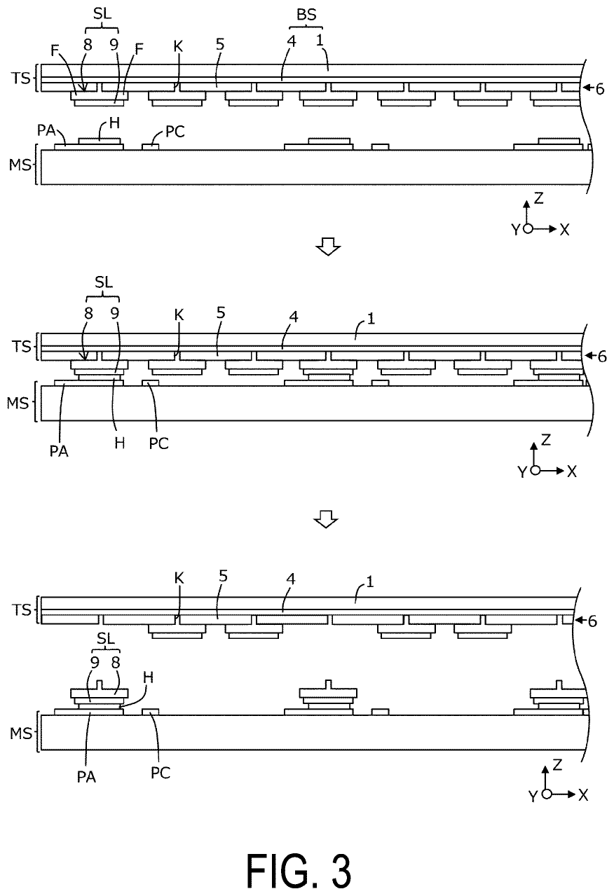

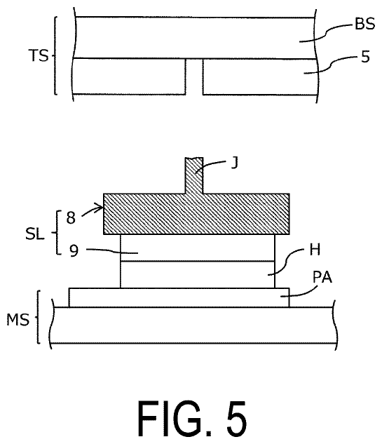

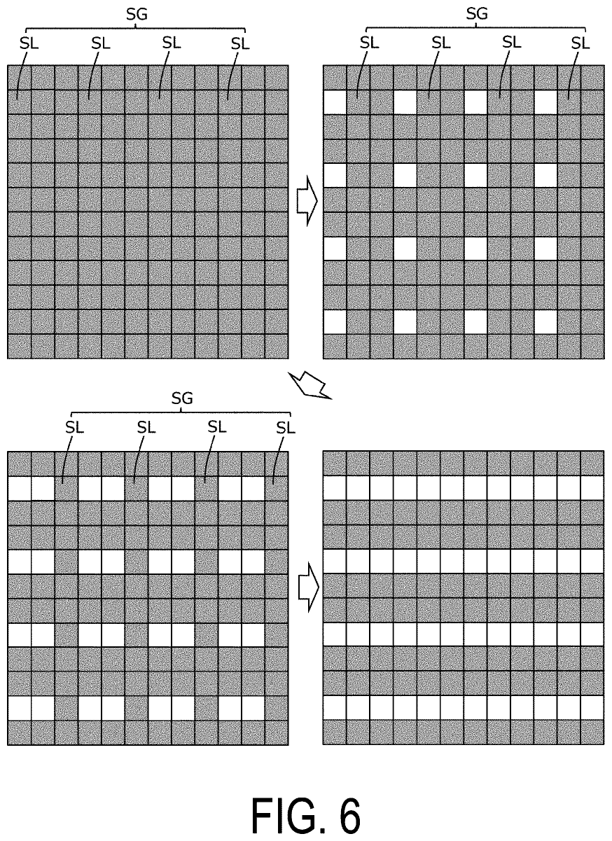

FIG. 1 is a flowchart illustrating a manufacturing method for a semiconductor element according to the present embodiment. FIG. 2 is a plan view illustrating a growth substrate and a plurality of elements. FIGS. 3 to 5 are cross-sectional views illustrating the manufacturing method for a semiconductor element according to the present embodiment. FIG. 6 is a plan view illustrating the manufacturing method for a semiconductor element according to the present embodiment. As illustrated in FIGS. 1 to 6, the manufacturing method for a semiconductor element according to the present embodiment includes bonding a plurality of elements SL, each including a semiconductor layer 8 grown on a growth substrate TS, to a surface of a support substrate MS (S10), applying an external force to a back surface UF of one of the growth substrate TS or the support substrate MS, thereby forming a pressure distribution having in-plane non-uniformity (S20), and peeling the plurality of elements SL bonded to the support substrate MS from the growth substrate TS (S30).

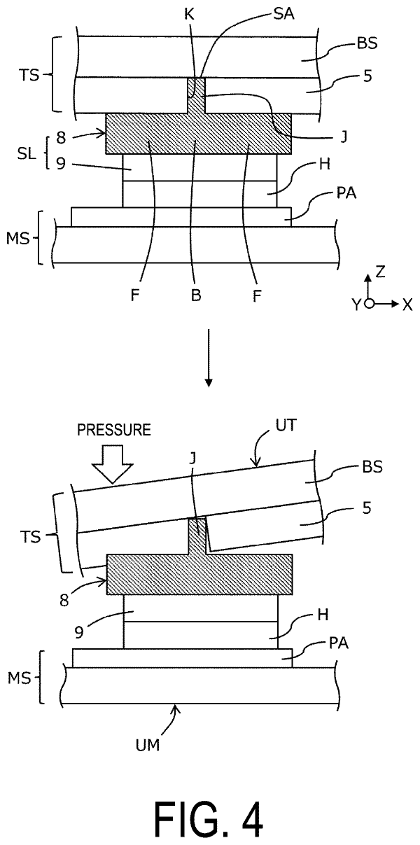

As illustrated in FIG. 4, in a state in which the plurality of elements SL are bonded to the surface of the support substrate MS, an external force is applied to a back surface UT of the growth substrate TS, for example, thereby forming a pressure distribution having in-plane non-uniformity, making it possible to incline the elements SL relative to the growth substrate TS and readily break coupling portions J. Specifically, a pressure distribution in which the pressure changes in a first direction X is formed, causing the coupling portion J with the growth substrate TS to incline relative to a normal line of the growth substrate TS and shearing stress to concentrate in the vicinity of an interface between the growth substrate TS and the coupling portion J, breaking the coupling portion J. Note that an external force may be applied to a back surface UM of the support substrate MS, thereby forming a pressure distribution having in-plane uniformity without change over time.

There has been a problem in which a process of transferring the plurality of elements on the growth substrate to the support substrate has a low yield. However, according to the manufacturing method for a semiconductor element of the present embodiment, the yield when transferring the plurality of elements SL to the support substrate MS is improved.

The growth substrate TS and the support substrate MS may be rigid substrates. Each of the growth substrate TS and the support substrate MS may include a silicon-based substrate (Si substrate or SiC substrate, for example). The growth substrate TS may include a mask substrate BS, and a mask pattern 6 including a mask 5 and an opening portion K. A bonding material that bonds the elements SL and the support substrate MS may have rigidity. This makes it possible to further increase the yield.

The semiconductor layer 8 includes a nitride semiconductor as a main constituent. The nitride semiconductor may be expressed by, for example, AlₓGa_{y}In_{z}N (0≤x≤1; 0≤y≤1; 0≤z≤1; x+y+z=1). Specific examples of the nitride semiconductor include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor include GaN, AlGaN, AlGaInN, and InGaN.

The semiconductor layer 8 may be a doped type (n-type including a donor, for example) or a non-doped type. The growth substrate TS includes a main substrate 1. The main substrate 1 and an underlying layer 4 may be collectively referred to as the base substrate BS. The growth substrate TS may include a plurality of seed regions SA arranged in stripes in the first direction X, and the plurality of elements SL may be respectively connected to the plurality of seed regions SA.

The plurality of elements SL may be formed spaced apart in the first direction X, and a gap GP may be formed between two of the elements SL adjacent to each other. The first direction X may be an a-axis direction (<11-20> direction) of the semiconductor layer 8 (nitride semiconductor such as GaN). A second direction Y may be an m-axis direction (<1-100> direction) of the semiconductor layer 8. A third direction Z (thickness direction of the semiconductor layer 8) may be a c-axis direction (<0001> direction) of the semiconductor layer 8.

As illustrated in FIGS. 2 to 4, the semiconductor layer 8 can be formed by an epitaxial lateral overgrowth (ELO) method with the underlying layer 4 (seed region SA) exposed under the opening portion K serving as a starting point. The underlying layer 4 may be, for example, a single layer of an AlN layer, a multiple layer of an AlN layer (bottom layer) and a GaN layer (top layer), or a multiple layer of an Al layer (bottom layer) and an AlN layer (top layer). The coupling portion J positioned in the opening portion K is an initial formation layer and is coupled to the underlying layer 4 (seed region SA) exposed. The base B, of the semiconductor layer 8, positioned above the opening portion K, serves as a dislocation inheritance portion in which a large number of threading dislocations occur, and a wing F positioned above the mask 5 serves as a low defect portion having a lower threading dislocation density as compared with that of the dislocation inheritance portion.

The base substrate BS may include the main substrate 1 that is a heterogeneous substrate having a lattice constant different from that of the semiconductor layer 8. The semiconductor layer 8 may include a GaN-based semiconductor, and the main substrate 1 that is the heterogeneous substrate may be a silicon substrate. In addition to the silicon substrate, examples of the heterogeneous substrate include a sapphire (Al₂O₃) substrate and a silicon carbide (SiC) substrate. A plane orientation of the main substrate 1 is, for example, the (111) plane of the silicon substrate, the (0001) plane of the sapphire substrate, or the 6H—SiC (0001) plane of the SiC substrate. These are merely examples, and the substrate and the plane orientation need only be those that facilitate growth of the semiconductor layer 8 by the ELO method.

The mask pattern 6 includes the mask 5 and the opening portion K. The opening portion K may function as a growth start hole that exposes a portion of the underlying layer 4 (seed region SA) and starts the growth of the semiconductor layer 8. The mask 5 may function as a selective growth mask (deposition suppression mask) for growing the semiconductor layer 8 in a lateral direction, and a surface of the mask 5 may form a growth suppression region (non-seed region) DA.

Examples of the mask 5 that can be used include a single-layer film including any one of a silicon oxide film (SiOx), a titanium nitride film (TiN or the like), a silicon nitride film (SiNx), a silicon oxynitride film (SiON), or a metal film having a high melting point (1000 °C or higher, for example), or a layered film including at least two thereof. A thermal oxide film obtained by performing thermal oxidation treatment on a silicon substrate, a silicon nitride substrate, or the like may be used as the mask 5. As the mask 5, a laminated film in which a silicon oxide film and a silicon nitride film are formed in this order can be used. An upper layer film that comes into contact with the semiconductor layer 8 may be a silicon nitride film.

The element SL may include a functional layer 9 positioned on the semiconductor layer 8. The functional layer 9 may include an active layer, a p-type layer, and electrodes (anode and cathode, for example). The active layer may have a quantum well structure. The semiconductor layer 8, the active layer, and the p-type layer may be made of a GaN-based semiconductor, and these layers may be continuously formed by a metal-organic chemical vapor deposition (MOCVD) device.

The support substrate MS may be a sub-mount substrate and may include electrode pads PA, PC. The element SL and the electrode pad PA may be bonded via solder H. The anode of the element SL and the electrode pad PA may be bonded via the solder H. The solder H may be a Sn—Au alloy.

As illustrated in FIGS. 3 and 6, step S10 in FIG. 1 may be selective transfer. That is, the plurality of elements SL bonded to the support substrate MS may be a selected element group SG selected from all elements on the growth substrate TS.

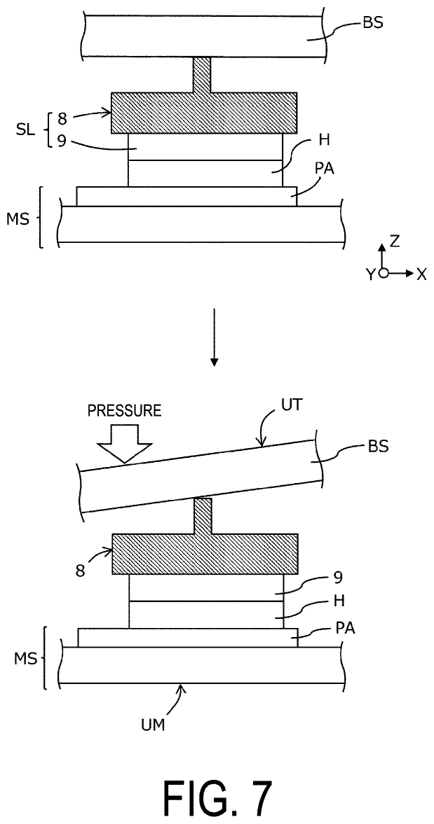

In FIGS. 1 to 5, the plurality of elements SL (selected element group) are bonded to the support substrate MS without removing the mask 5 of the growth substrate TS. In this case, as illustrated in FIG. 4, when the element SL is inclined relative to the growth substrate TS, a part of the element SL may sink into the mask 5. FIG. 7 is a cross-sectional view illustrating the manufacturing method for a semiconductor element according to the present embodiment. As illustrated in FIG. 7, after the mask 5 of the growth substrate TS is removed by wet etching or the like, the plurality of elements SL (selected element group) may be bonded to the support substrate MS, and the elements SL may be inclined relative to the growth substrate TS to break the coupling portions J.

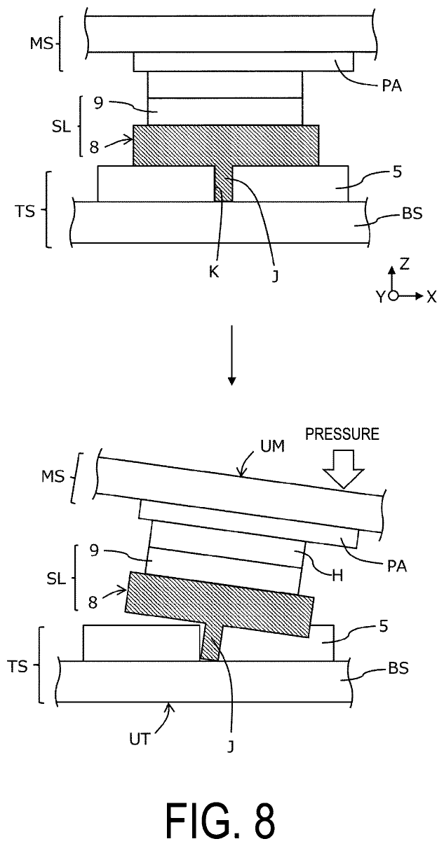

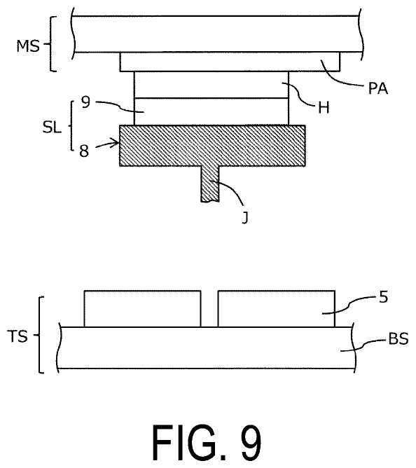

FIGS. 8 and 9 are cross-sectional views illustrating the manufacturing method for a semiconductor element according to the present embodiment. Although an external force is applied to the back surface UF of the growth substrate TS in FIGS. 3 and 4, application is not limited thereto. As illustrated in FIGS. 8 and 9, in a state in which the plurality of elements SL are bonded to the surface of the support substrate MS, the elements SL may be inclined relative to the growth substrate TS and the coupling portions J may be readily broken by applying an external force to the back surface UM of the support substrate MS, thereby forming a pressure distribution having in-plane non-uniformity. Specifically, a pressure distribution in which the pressure changes in the first direction X is formed, causing the coupling portion J with the growth substrate TS to incline relative to the normal line of the growth substrate TS and shearing stress to concentrate in the vicinity of the interface between the growth substrate TS and the coupling portion J, breaking the coupling portion J. An external force may be applied to the back surface UT of the growth substrate TS, thereby forming a pressure distribution having in-plane uniformity without change over time.

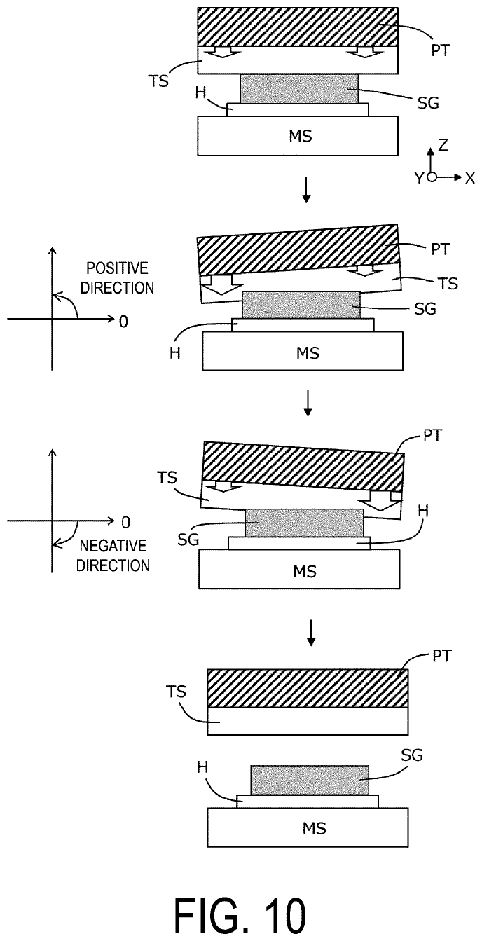

FIG. 10 is a cross-sectional view illustrating the manufacturing method for a semiconductor element according to the present embodiment. As illustrated in FIG. 10, the pressure distribution on the back surface of the growth substrate TS may be changed over time. For example, a plate PT inclined by a predetermined positive angle about an axis (Y direction, m-axis of semiconductor layer 8) orthogonal to the first direction X is brought into pressure contact with the back surface of the growth substrate TS, and then the plate PT inclined by a predetermined negative angle is brought into pressure contact with the back surface. The predetermined positive angle may be from 1° to 3°, and the predetermined negative angle may be from −1° to −3°. Thus, the selected element group SG (plurality of elements SL to be selectively transferred) can be inclined in the positive direction and the negative direction relative to the growth substrate TS and, even if the selected element group SG includes the coupling portions J (refer to FIG. 4) not broken by the inclination in the positive direction, the coupling portions J can be broken by the inclination in the negative direction, increasing the transfer yield of the selected element group SG. Here, when the inclination is less than 1°, the inclination is insufficient, decreasing the yield. When the inclination is 3° or more, the plate PT may float from the growth substrate TS, making it no longer possible to apply force appropriately.

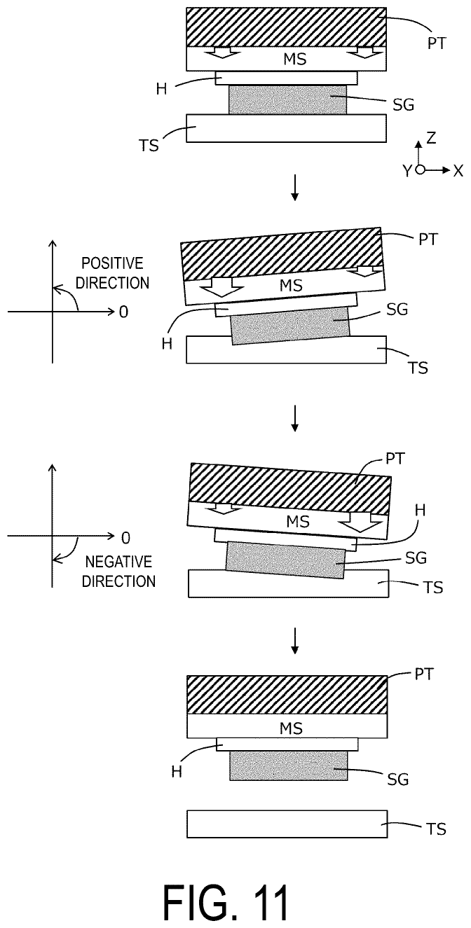

FIG. 11 is a cross-sectional view illustrating the manufacturing method for a semiconductor element according to the present embodiment. As illustrated in FIG. 11, the pressure distribution on the back surface of the support substrate MS may be changed over time. For example, the plate PT inclined by a predetermined positive angle about an axis (Y direction, m-axis of semiconductor layer 8) orthogonal to the first direction X is brought into pressure contact with the back surface of the support substrate MS, and then the plate PT inclined by a predetermined negative angle is brought into pressure contact with the back surface. The predetermined positive angle may be from 1° to 3°, and the predetermined negative angle may be from −1° to −3°. Thus, the selected element group SG (plurality of elements SL to be selectively transferred) can be inclined in the positive direction and the negative direction relative to the growth substrate TS and, even if the selected element group SG includes the coupling portions J (refer to FIG. 4) not broken by the inclination in the positive direction, the coupling portions J can be broken by the inclination in the negative direction, increasing the transfer yield of the selected element group SG.

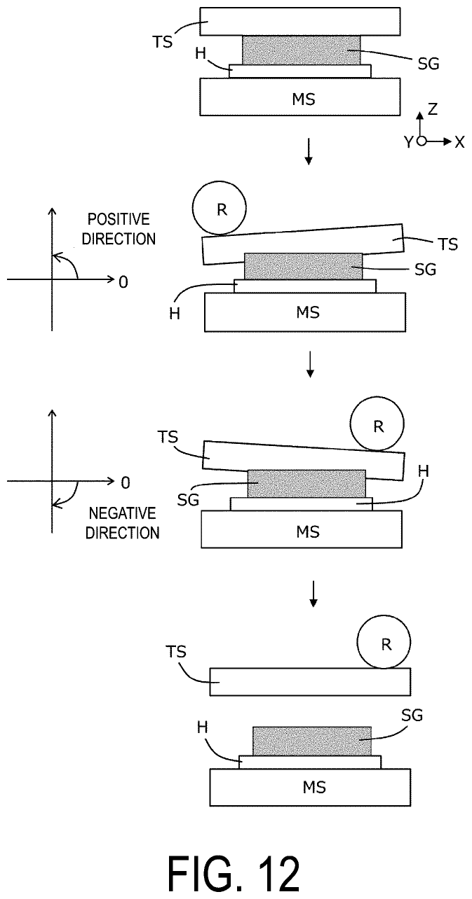

FIG. 12 is a cross-sectional view illustrating the manufacturing method for a semiconductor element according to the present embodiment. As illustrated in FIG. 12, a roller R brought into pressure contact with the back surface of the growth substrate TS may be moved in the first direction X, thereby changing the pressure distribution on the back surface of the growth substrate TS over time. Thus, the selected element group SG (plurality of elements SL to be selectively transferred) can be inclined in the positive direction and the negative direction relative to the growth substrate TS and, even if the selected element group SG includes the coupling portions J (refer to FIG. 4) not broken by the inclination in the positive direction, the coupling portions J can be broken by the inclination in the negative direction, increasing the transfer yield of the selected element group SG. The growth substrate TS may be absorbed by the roller R after the transfer of the selected element group SG.

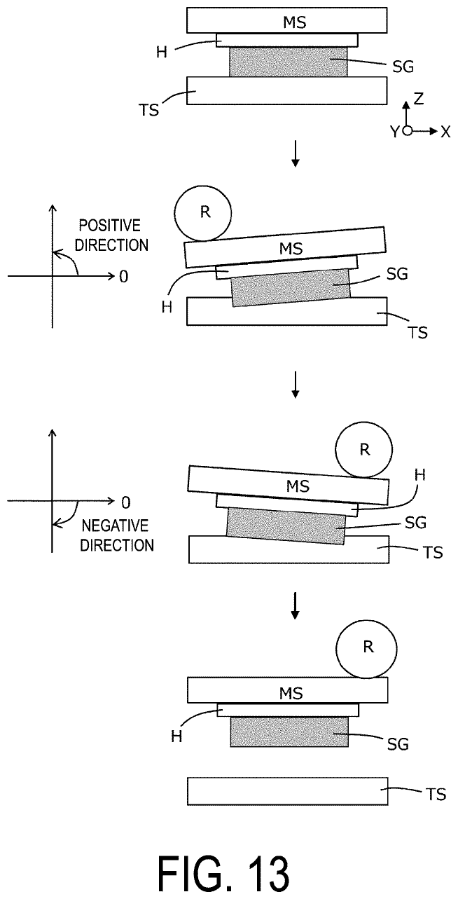

FIG. 13 is a cross-sectional view illustrating the manufacturing method for a semiconductor element according to the present embodiment. As illustrated in FIG. 13, the roller R brought into pressure contact with the back surface of the support substrate MS may be moved in the first direction X, thereby changing the pressure distribution on the back surface of the support substrate MS over time. Thus, the selected element group SG (plurality of elements SL to be selectively transferred) can be inclined in the positive direction and the negative direction relative to the growth substrate TS and, even if the selected element group SG includes the coupling portions J (refer to FIG. 4) not broken by the inclination in the positive direction, the coupling portions J can be broken by the inclination in the negative direction, increasing the transfer yield of the selected element group SG. The support substrate MS (including the selected element group SG) may be absorbed by the roller R after the transfer of the selected element group SG.

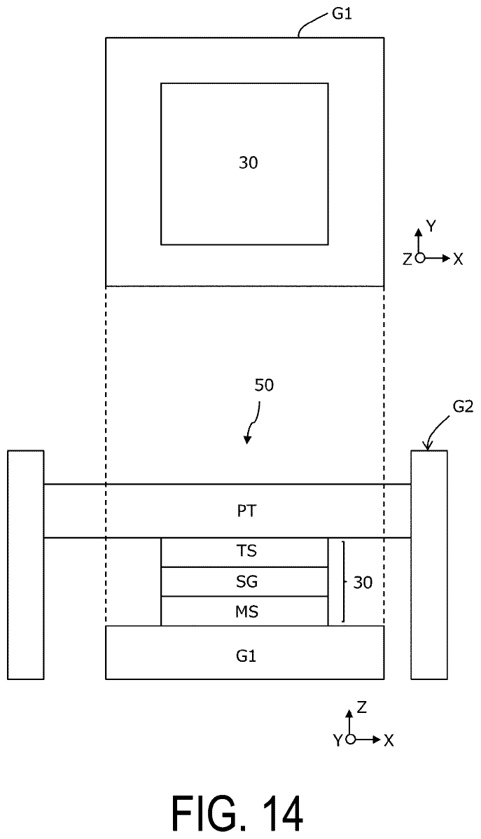

FIG. 14 is a cross-sectional view illustrating a manufacturing device for a semiconductor element according to the present embodiment. As illustrated in FIG. 14, a manufacturing device 50 for a semiconductor element may include a device G1 capable of absorbing, holding, and transporting a workpiece 30 from a lower surface, and a device G2 that drives the plate PT capable of changing in inclination while applying a force in a compression direction from an upper surface of the workpiece 30. The device G1 is capable of moving in the X direction, moving in the Y direction, and rotating in an XY plane, and matches a position of the workpiece 30 and an orientation of the selected element group SG relative to the plate PT. The device G2 is capable of moving in the Z direction and rotating in an XZ plane. After applying a force to the workpiece 30, the manufacturing device 50 for a semiconductor element separates the workpiece upper surface and the workpiece lower surface while holding the two by absorption, peeling the selected element group SG from the growth substrate TS.

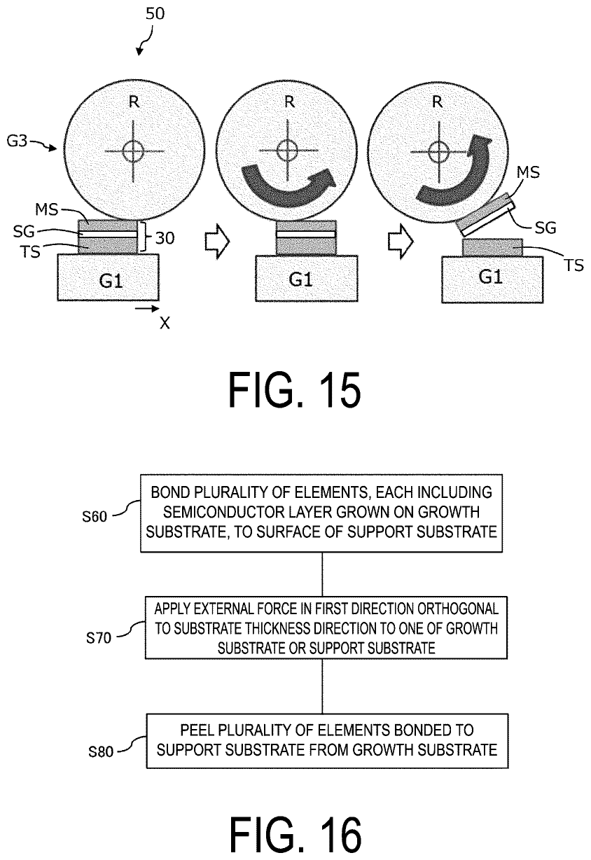

FIG. 15 is a cross-sectional view illustrating the manufacturing device for a semiconductor element according to the present embodiment. As illustrated in FIG. 15, the manufacturing device 50 for a semiconductor element may include the device G1 capable of absorbing, holding, and transporting the workpiece 30 from the lower surface, and a device G3 that drives the roller R that applies a force in the compression direction from the upper surface of the workpiece 30. The device G1 is capable of moving in the X direction, moving in the Y direction, and rotating in the XY plane, and matches the position of the workpiece 30 and the orientation of the selected element group SG relative to the roller R. The manufacturing device 50 for a semiconductor element moves the device G1 in the X direction, applying a force in the compression direction by the roller R from one end to the other end of the support substrate MS. After the roller R is brought into an absorption state and a force is applied to the workpiece 30, a workpiece top side (support substrate MS and selected element group SG) is absorbed by the roller R side, resulting in peeling. Although the pressure of the roller R is applied to the support substrate MS in FIG. 15, application is not limited thereto, and the pressure of the roller R may be applied to the growth substrate TS.

FIG. 16 is a flowchart illustrating the manufacturing method for a semiconductor element according to the present embodiment. As illustrated in FIG. 16, the manufacturing method for a semiconductor element according to the present embodiment includes bonding the plurality of elements SL, each including the semiconductor layer 8 grown on the growth substrate TS, to the surface of the support substrate MS (S60), applying an external force to one of the growth substrate TS or the support substrate MS in a first direction (X direction) orthogonal to a substrate thickness direction (S70), and peeling the plurality of elements SL bonded to the support substrate MS from the growth substrate TS (S80).

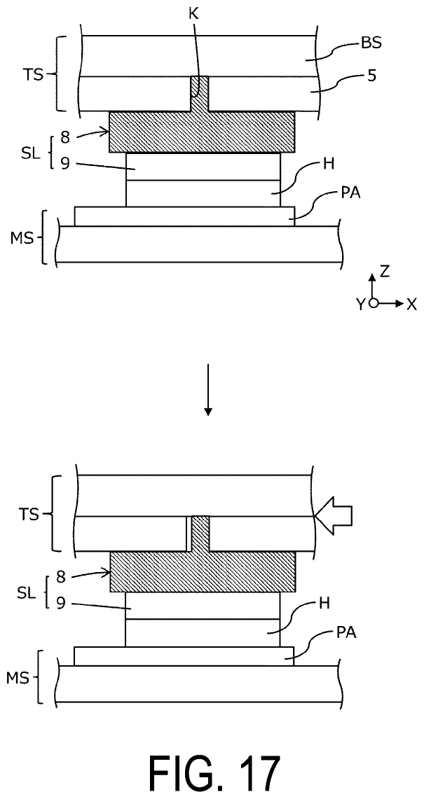

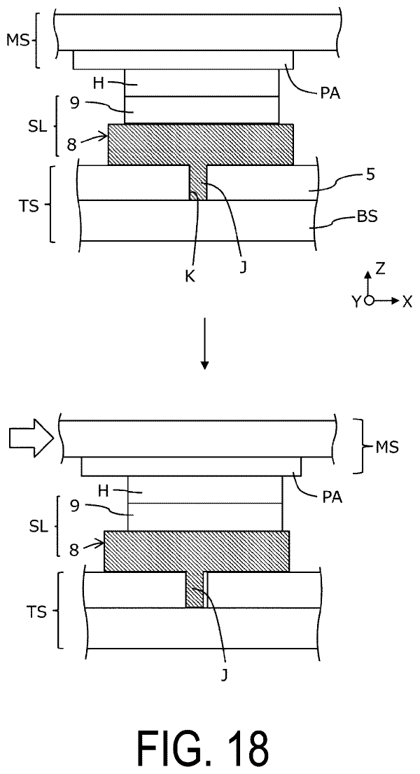

FIGS. 17 and 18 are cross-sectional views illustrating the manufacturing method for a semiconductor element according to the present embodiment. As illustrated in FIG. 17, an external force in the first direction (X direction) may be applied to the growth substrate TS. In this case, an external force in a direction (−X direction) opposite to the first direction may be applied to the support substrate MS. As illustrated in FIG. 18, an external force in the first direction (X direction) may be applied to the support substrate MS. In this case, an external force in the direction (−X direction) opposite to the first direction may be applied to the growth substrate TS.

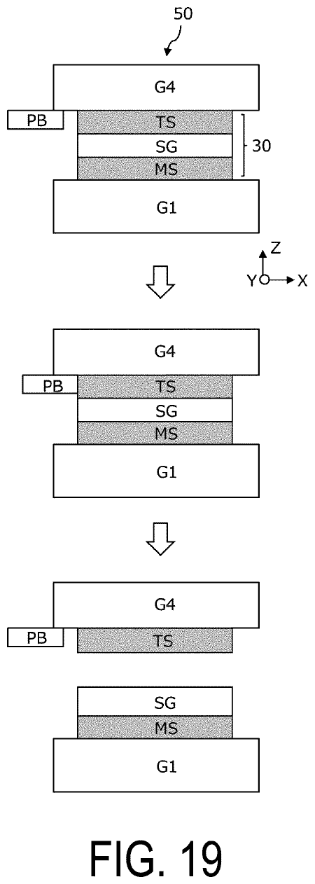

FIG. 19 is a cross-sectional view illustrating the manufacturing device for a semiconductor element according to the present embodiment. As illustrated in FIG. 19, the manufacturing device 50 for a semiconductor element may include the device G1 capable of absorbing, holding, and transporting the workpiece 30 from the lower surface, and a device G4 that absorbs and holds the upper surface of the workpiece 30 and includes a pressure portion PB that applies a force in the first direction (X direction) to the workpiece 30. After the external force in the first direction (X direction) is applied to the growth substrate TS by the pressure portion PB in a state of the upper surface and the lower surface of the workpiece 30 being held by absorption, the workpiece upper surface and the workpiece lower surface are separated while held by absorption, thereby peeling the selected element group SG from the growth substrate TS. Although an external force in the first direction (X direction) is applied to the growth substrate TS in FIG. 19, application is not limited thereto. An external force in the first direction (X direction) may be applied to the support substrate MS.

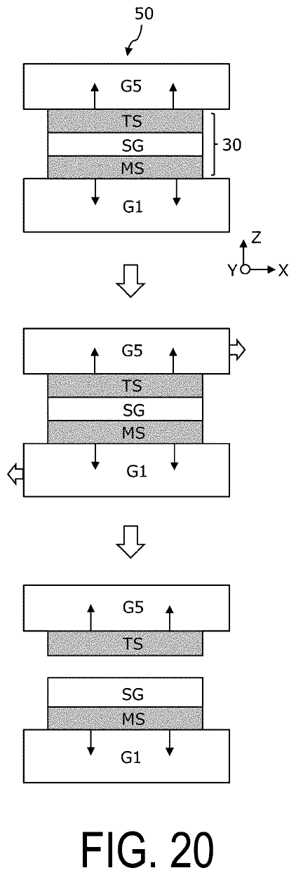

FIG. 20 is a cross-sectional view illustrating the manufacturing device for a semiconductor element according to the present embodiment. As illustrated in FIG. 20, the manufacturing device 50 for a semiconductor element may include the device G1 capable of absorbing, holding, and transporting the workpiece 30 from the lower surface, and a device G5 that moves in the first direction (X direction) while absorbing and holding the upper surface of the workpiece 30. In the manufacturing device 50 for a semiconductor element, in a state in which the upper surface and the lower surface of the workpiece 30 are held by absorption, the device G5 moves by a small amount in the first direction (X direction) and the device G1 moves by a small amount in the direction (−X direction) opposite to the first direction, and thus the workpiece upper surface and the workpiece lower surface are subsequently separated while held by absorption, thereby peeling the selected element group SG from the growth substrate TS.

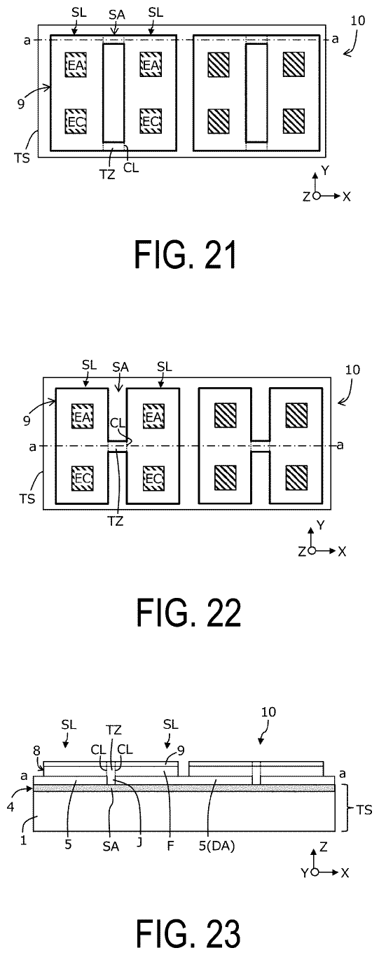

FIGS. 21 and 22 are plan views of configurations of the semiconductor substrate according to the present embodiment. FIG. 23 is a cross-sectional view of FIGS. 21 and 22. As illustrated in FIGS. 21 to 23, in a semiconductor substrate 10 including the growth substrate and the semiconductor element, the element SL including the wing F (one wing) of the semiconductor layer 8 includes an anode EA and a cathode EC, and the element SL may be held by the growth substrate (template substrate) TS via a tether TZ positioned on the seed region SA. In this case, the element SL can be separated from the growth substrate TS by cutting (breaking) a boundary CL between the tether TZ and the wing F (one wing) as well as the functional layer 9 overlapping the wing F by using the manufacturing method of a semiconductor element according to the present embodiment. The element SL may be a light-emitting diode (LED). One tether TZ may be provided in a center portion (FIG. 21), or a plurality of tethers TZ may be provided at intervals (FIG. 22). In the semiconductor substrate 10 illustrated in FIGS. 21 to 23, the tether TZ is formed by patterning (partially removing by dry etching or the like) a region positioned on the seed region SA in the semiconductor layer 8 and the functional layer 9 overlapping the semiconductor layer 8.

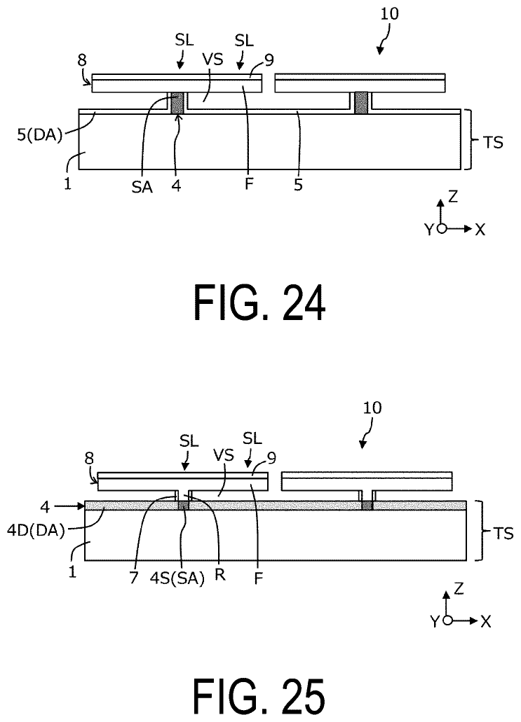

FIGS. 24 and 25 are cross-sectional views, each illustrating a configuration of the semiconductor substrate according to the present embodiment. As illustrated in FIG. 24, a gap VS may be provided between the wing F (one wing) of the semiconductor layer 8 and the growth substrate TS. In the semiconductor substrate 10 in FIG. 24, the underlying layer 4 is formed in a ridge shape and a side surface of the underlying layer 4 is covered with the mask 5, making it possible to grow the wing F of the semiconductor layer 8 laterally in a state of floating from the growth substrate TS.

Using the manufacturing method for a semiconductor element according to the present embodiment, the elements SL including the semiconductor layer 8 (including both wings) and the functional layer 9 overlapping the semiconductor layer 8 may be obtained, or the elements SL including the wings F and the functional layer 9 overlapping the wings F may be obtained, from the semiconductor substrate 10 in FIG. 24. The elements SL may be separated from the growth substrate TS after forming a tether structure (structure in which the semiconductor layer 8 and the functional layer 9 on the seed region SA are patterned) such as illustrated in FIGS. 21 and 22.

As illustrated in FIG. 25, the gap VS may be provided between the wing F (one wing) of the semiconductor layer 8 and the growth substrate TS. In the semiconductor substrate 10 in FIG. 25, after a raised portion R having a ridge shape (GaN-based semiconductor portion, for example) and a growth suppression film 7 (silicon nitride film, for example) in contact with the raised portion R are continuously formed on the growth substrate TS, the wings F of the semiconductor layer 8 (nitride semiconductor layer) can be laterally grown in a state of floating from the growth substrate TS. In the growth substrate TS (template substrate) in FIG. 25, a modified region 4D and an unmodified region 4S are formed in the underlying layer 4, the unmodified region 4S functioning as the seed region SA and the modified region 4D functioning as the growth suppression region (non-seed region) DA. The modified region 4D can be formed by performing plasma treatment or the like on the underlying layer 4 (AIN layer, for example).

Using the manufacturing method for a semiconductor element according to the present embodiment, the elements SL including the semiconductor layer 8 (including both wings) and the functional layer 9 overlapping the semiconductor layer 8 may be obtained, or the elements SL including the wings F and the functional layer 9 overlapping the wings F may be obtained, from the semiconductor substrate 10 in FIG. 25. The elements SL may be separated from the growth substrate TS after forming a tether structure (structure in which the semiconductor layer 8 and the functional layer 9 on the seed region SA are patterned) such as illustrated in FIGS. 21 and 22.

### SUPPLEMENTARY NOTE

The foregoing disclosure has been presented for purposes of illustration and description, and not limitation. It is noted that many variations will be apparent to those skilled in the art based on these illustrations and descriptions, and these variations are included in the embodiments.

### REFERENCE SIGNS

1 Main substrate
4 Underlying layer
5 Mask
6 Mask pattern
8 Semiconductor layer
30 Workpiece
50 Manufacturing device for semiconductor element
K Opening portion
B Base
F Wing
J Coupling portion
H Solder
SG Selected element group
G1 to G5 Device
PA, PC Pad electrode
SL Element
SA Seed region
MS Support substrate
TS Growth substrate

1. A manufacturing method for a semiconductor element, the manufacturing method comprising:
bonding a plurality of elements, each comprising a semiconductor layer grown on a growth substrate, to a surface of a support substrate;
applying an external force to a back surface of one of the growth substrate or the support substrate, thereby forming a pressure distribution having in-plane non-uniformity; and
peeling the plurality of elements bonded to the support substrate from the growth substrate.

2. The manufacturing method for a semiconductor element according to claim 1, wherein
the pressure distribution is changed over time.

3. The manufacturing method for a semiconductor element according to claim 1, wherein
the external force is applied to incline the plurality of elements relative to the growth substrate, thereby breaking respective coupling portions with the growth substrate.

4. The manufacturing method for a semiconductor element according to claim 1, wherein
an external force is applied to a back surface of the other of the growth substrate or the support substrate, thereby forming a pressure distribution having in-plane uniformity without change over time.

5. The manufacturing method for a semiconductor element according to claim 1, wherein
the growth substrate and the support substrate are rigid substrates.

6. The manufacturing method for a semiconductor element according to claim 1, wherein
the growth substrate comprises a plurality of seed regions arranged in stripes in a first direction, and
the plurality of elements are respectively connected to the plurality of seed regions.

7. The manufacturing method for a semiconductor element according to claim 6, wherein
the plurality of elements are formed spaced apart in the first direction.

8. The manufacturing method for a semiconductor element according to claim 6, wherein
in the pressure distribution, pressure changes in the first direction.

9. The manufacturing method for a semiconductor element according to claim 6, wherein
a plate inclined by a predetermined positive angle about an axis orthogonal to the first direction is brought into pressure contact with the back surface of one of the growth substrate or the support substrate.

10. The manufacturing method for a semiconductor element according to claim 9, wherein
after the plate inclined by the predetermined positive angle is brought into pressure contact with the back surface of one of the growth substrate or the support substrate, a plate inclined by a predetermined negative angle is brought into pressure contact with the back surface.

11. The manufacturing method for a semiconductor element according to claim 9, wherein
the predetermined positive angle is from 1° to 3°.

12. The manufacturing method for a semiconductor element according to claim 6, wherein a roller brought into pressure contact with the back surface of one of the growth substrate or the support substrate is moved in the first direction.

13. The manufacturing method for a semiconductor element according to claim 6, wherein:
the growth substrate comprises a mask positioned between the plurality of seed regions, and
the plurality of elements are peeled from the growth substrate without removing the mask.

14. The manufacturing method for a semiconductor element according to claim 1, wherein
the plurality of elements are selectively bonded to the support substrate from an element group positioned on the growth substrate.

15. A manufacturing device for a semiconductor element, the manufacturing device being configured to peel a plurality of elements, each comprising a semiconductor layer grown on a growth substrate, from the growth substrate, wherein
an external force is applied to a back surface of one of a support substrate supporting the plurality of elements or the growth substrate, thereby forming a pressure distribution having in-plane non-uniformity.

16. The manufacturing device for a semiconductor element according to claim 15, wherein
the pressure distribution is changed over time.

17. The manufacturing device for a semiconductor element according to claim 16, the manufacturing device comprising:
a plate; and
a driving mechanism for the plate, wherein
the driving mechanism is configured to bring the plate inclined in a positive direction relative to the back surface into pressure contact with the back surface, and then bring the plate inclined in a negative direction relative to the back surface into pressure contact with the back surface.

18. The manufacturing device for a semiconductor element according to claim 16, the manufacturing device comprising:
a roller; and
a driving mechanism for the roller, wherein
the driving mechanism is configured to rotate the roller while bringing the roller into pressure contact with the back surface of one of the growth substrate or the support substrate.

19. The manufacturing device for a semiconductor element according to claim 18, further comprising:
a workpiece moving mechanism configured to move the growth substrate and the support substrate to an orientation corresponding to a rotation direction of the roller.

20. A manufacturing method for a semiconductor element, the manufacturing method comprising:
bonding a plurality of elements, each comprising a semiconductor layer grown on a growth substrate, to a surface of a support substrate;
applying an external force to one of the growth substrate in a first direction orthogonal to a substrate thickness direction; and
peeling the plurality of elements bonded to the support substrate from the growth substrate.
